(19) United States
(12) Patent Application Publication
(10) Pub. No.: US 2016/0280536 A1
(43) Pub. Date: Sep. 29, 2016

(54) Method for Manufacturing Hollow Structure

(71) Applicant: TOKYO ELECTRON LIMITED, Tokyo (JP)

(72) Inventors: Kippei SUGITA, Nirasaki-shi (JP); Hiroyuki HASHIMOTO, Nirasaki-shi (JP)

(21) Appl. No.: 14/777,778

(22) PCT Filed: Mar. 17, 2014
(86) PCT No.: PCT/JP2014/057182

§ 371 Date: Sep. 17, 2015

(30) Foreign Application Priority Data
Mar. 28, 2013 (JP) 2013-068958

(51) Int. Cl. B81C 1/00

(52) U.S. Cl. CPC B81C 1/00047; B81C 2201/0132; B81C 2201/0108; B81C 2201/0104

(57) ABSTRACT

A hollow structure is manufactured by preparing a lower structure which includes a concave portion, depositing a sacrifice film composed of an organic film on the lower structure by a vapor deposition polymerization method to bury the concave portion with the sacrifice film, removing an unnecessary portion of the sacrifice film, forming an upper structure on the sacrifice film with the unnecessary portion removed, and forming an air gap between the lower structure and the upper structure by removing the sacrifice film.

### TECHNICAL FIELD

The present disclosure relates to a method for manufacturing a hollow structure.

### BACKGROUND

Conventionally, a semiconductor device in which an air gap of a hollow is formed or a hollow structure in a MEMS device is known (see, e.g., Patent Documents 1 and 2).

When manufacturing such a hollow structure, a sacrifice film process is generally used. More specifically, a sacrifice film made of polyimide or the like is first buried on a lower structure having grooves or the like. An upper structure is formed on the sacrifice film. Subsequently, an air gap is formed by removing the sacrifice film.

In a case where the sacrifice film is formed using, e.g., polyimide, it is typical that a polyamide acid (polyamic acid), which is a precursor of the polyimide, is dissolved in an organic solvent to prepare a polyamide acid solution. Then, the polyamide acid solution is coated on a lower structure and is heated to, e.g., about 350 degrees C., thereby forming a sacrifice film made of polyimide.

### PRIOR ART DOCUMENTS

### Patent Documents

Patent Document 1: Japanese laid-open publication No. 2006-269537

Patent Document 2: Japanese laid-open publication No. 2011-83881

However, when a sacrifice film is formed by coating and heating a polyamide acid solution, a polyimide film is formed by the dehydration reaction of a polyamide acid. Thus, the polyimide film contracts due to dehydration, whereby stress is generated in the polyimide film.

If the shape pattern of a groove or the like formed in a lower structure has a minute size of, e.g., the order of nanometers, a polyamide solution is not evenly spread into the minute groove or the like during a coating process. It is therefore difficult to form an air gap having a minute structure.

The present disclosure provides some embodiments of a method for manufacturing a hollow structure, capable of forming an air gap with high accuracy using a sacrifice film forming process with a high degree of being buried at low stress levels.

### SUMMARY

According to one embodiment of the present disclosure, there is provided a method for manufacturing a hollow structure. The method includes preparing a lower structure which includes a concave portion, and depositing a sacrifice film composed of an organic film on the lower structure by a vapor deposition polymerization method to bury the concave portion with the sacrifice film.

Next, an unnecessary portion of the sacrifice film is removed, and an upper structure on the sacrifice film with the unnecessary portion removed is formed.

Finally, an air gap between the lower structure and the upper structure is formed by removing the sacrifice film.

According to the present disclosure, it is possible to manufacture a hollow structure having an accurately-formed air gap

### BRIEF DESCRIPTION OF THE DRAWINGS

FIGS. 1A to 1E are views illustrating one example of a method for manufacturing a hollow structure according to a first embodiment of the present disclosure. FIG. 1A is a view illustrating one example of a lower structure preparing process. FIG. 1B is a view illustrating one example of a sacrifice film forming process. FIG. 1C is a view illustrating one example of an unnecessary portion removing process. FIG. 1D is a view illustrating one example of an upper structure forming process. FIG. 1E is a view illustrating one example of a sacrifice film removing process.

FIGS. 2A and 2B are views illustrating one example of a sacrifice film forming process using a vapor deposition polymerization method in manufacturing a hollow structure according to the first embodiment of the present disclosure. FIG. 2A is a view illustrating one example of a film forming apparatus which performs film formation of a resin film using a vapor deposition polymerization method. FIG. 2B is a view illustrating monomers as raw materials and one example of a reaction thereof.

FIG. 3 is a view illustrating a state in which concave portions are buried by a vapor deposition polymerization method.

FIGS. 4A to 4F are views illustrating one example of a method for manufacturing a hollow structure according to a second embodiment of the present disclosure. FIG. 4A is a view illustrating one example of a lower structure preparing process. FIG. 4B is a view illustrating one example of a sacrifice film forming process. FIG. 4C is a view illustrating one example of an unnecessary portion removing process. FIG. 4D is a view illustrating one example of a sacrifice film from which an unnecessary portion has been removed. FIG. 4E is a view illustrating one example of an upper structure forming process. FIG. 4F is a view illustrating one example of a sacrifice film removing process.

FIGS. 5A to 5E are views illustrating one example of a method for manufacturing a hollow structure according to a third embodiment of the present disclosure. FIG. 5A is a view illustrating one example of a lower structure preparing process. FIG. 5B is a view illustrating one example of a sacrifice film forming process and a planarization process. FIG. 5C is a view illustrating one example of a first upper structure forming process. FIG. 5D is a view illustrating one example of a second upper structure forming process. FIG. 5E is a view illustrating one example of a sacrifice film removing process.

### EXPLANATION OF REFERENCE NUMERALS

10: substrate, 20 or 25: concavo-convex pattern, 21 or 26: convex portion, 22 or 27: concave portion, 30 or 31: lower structure, 40 or 45: sacrifice film, 41, 51, 53 or 57: opening portion, 50, 52, 55 or 56: upper structure

### DETAILED DESCRIPTION

Embodiments for carrying out the present disclosure will now be described with reference to the drawings.

### First Embodiment

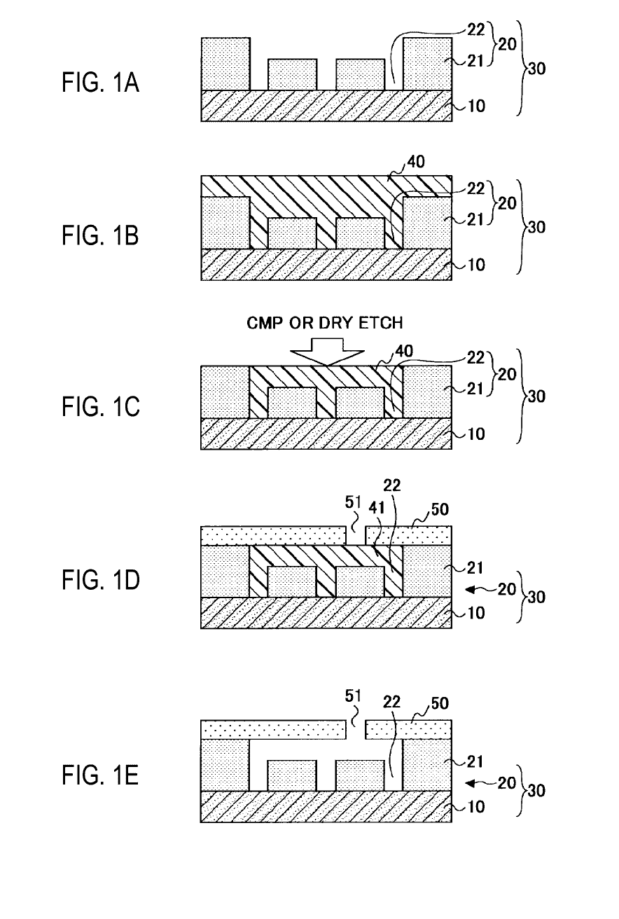

FIGS. 1A to 1E are views illustrating one example of a method for manufacturing a hollow structure according to a first embodiment of the present disclosure. FIG. 1A is a view illustrating one example of a lower structure preparing process. In the lower structure preparing process, a lower structure 30 having a concavo-convex pattern 20 is prepared. The concavo-convex pattern 20 of the lower structure 30 is formed by forming convex portions 21 on a substrate 10 at a predetermined interval and forming concave portions 22 between the convex portions 21.

The substrate 10 constitutes a bottom of the lower structure 30 and becomes a reference plane of the lower structure 30. The substrate 10 may be made of various materials including a semiconductor material and may be, e.g., a silicon substrate made of silicon. If necessary, an SOI (Silicon-on-Insulator) substrate or the like may be used as the substrate 10.

The concavo-convex pattern 20 is a pattern having a concavo-convex shape, which is formed on a surface of the substrate 10. The concavo-convex pattern 20 includes convex portions 21 and concave portions 22. The concavo-convex pattern 20 may be formed in various shapes depending on the use of a hollow structure. The surface of the substrate 10 becomes bottoms of the concave portions 22. The convex portions 21 are discretely formed from the surface of the substrate 10, thereby forming the concave portions 22 on the side surfaces of the convex portions 21.

The convex portions 21 are convex structures provided to form the concavo-convex pattern 20 on the surface of the substrate 10. Depending on the use of the hollow structure, the convex portions 21 may be made of various materials as long as a specified concavo-convex pattern 20 can be formed on the surface of the substrate 10. The convex portions 21 may be made of a metallic material such as, e.g., copper (Cu), tungsten (W) or the like. Moreover, the convex portions 21 may be made of a semiconductor material such as Si or the like, or an insulating material such as SiO₂ or the like. The material used as the convex portions 21 may be selected in view of electric properties, chemical properties and mechanical strength in addition to the shapes thereof. For example, if it is desired to form the convex portions 21 with a conductive material, a metallic material such as, e.g., Cu or W can be used. If it is desired to form the convex portions 21 with an insulating material, an insulating material such as, e.g., SiO₂ can be used. In this way, the material of the convex portions 21 can be decided depending on the use of the hollow structure.

By forming the convex portions 21, the regions where the convex portions 21 are not formed inevitably become the concave portions 22. Thus, the shape of the convex portions 21 may be appropriately decided in light of the relationship with the concave portions 22. As shown in FIG. 1A, the concavity depth of the concave portions 22 can be adjusted by changing the height of the convex portions 21. In FIG. 1A, the upper surface of each of the convex portions 21 is formed in a horizontal surface and the side surface of each of the convex portions 21 is formed in a vertical surface. However, the shape of the upper surface and the side surface of each of the convex portions 21 may be appropriately changed depending on the use of the hollow structure. For example, the side surface of each of the convex portions 21 may be formed as an inclined surface and the concave portions 22 may be configured to form grooves or holes having a tapered shape.

The concave portions 22 may be grooves or may be holes such as through-holes or the like. Generally, in the case where the hollow structure is used as a wiring structure, grooves (tranches) or holes (vias) are mainly formed as the concave portions 22. In the case where the hollow structure is used as a structure for MEMS (Micro Electro Mechanical Systems) used as a sensor or an actuator, the concave portions 22 are formed in various shapes depending on the use of the hollow structure. In this way, the concave portions 22 may be formed in various shapes depending on the use of the hollow structure.

Furthermore, the concavo-convex pattern 20 may be formed by forming, on the substrate 10, a layer with the same material as the convex portions 20 at a thickness equal to or larger than the thickness of the highest convex portions 20 and removing unnecessary parts from the layer through etching. Although FIG. 1A shows a state in which the lower structure 30 having the concavo-convex pattern 20 formed in advance is prepared, the lower structure 30 may be prepared by performing the aforementioned etching process. In this case, the lower structure preparing process may be called a lower structure forming process.

In the lower structure 30 illustrated in FIG. 1A, the concavo-convex pattern 20 including the concave portions 22 is formed by forming the convex portions 21 on the substrate 10. If there is an available processing technique, the lower structure 30 may be formed only with the material which constitutes the convex portions 22. If a desired shape can be realized as a whole, the lower structure 30 can be prepared by a variety of methods.

FIG. 1B is a view illustrating one example of a sacrifice film forming process. In the sacrifice film forming process, a sacrifice film 40 composed of an organic film is deposited and formed on the surface of the lower structure 30 using a vapor deposition polymerization method. At this time, the concave portions 22 are buried as the sacrifice film 40. The sacrifice film 40 is also formed on the upper surfaces of the convex portions 21. Thus, the concavo-convex pattern 20 is covered by the sacrifice film 40.

In this regard, an organic film is used as the sacrifice film 40. The sacrifice film 40 is formed by a vapor deposition polymerization method. The sacrifice film 40 may be one of various polymer films, for example, a polyimide film. In a conventional sacrifice film forming process, a polyimide film was formed by coating a polyamide acid solution on the surface of the lower structure 30 and heating the polyamide acid solution at a temperature of about 350 degrees C. for imidization. However, in such a method, the polyimide film is contracted when water disappears due to generation of the dehydration reaction caused by the heating. Thus, a stress is generated in the polyimide film. In a conventional process, the width of the concave portions 22 is in the micrometer-order level of several tens of μm and the depth of the concave portions 22 is in the micrometer-order level of several hundreds of μm. However, in recent years, it is expected that, due to the miniaturization requirement of a wiring structure or a MEMS device, the width of the concave portions 22 is required to be in the nanometer-order level of, e.g., several tens of nm and the depth of the concave portions 22 is required to be in the nanometer-order level of, e.g., several hundreds of nm There is a possibility that a polyamide acid solution is not sufficiently filled in the concave portions 22 of a nanometer-order level.

For that reason, in the method for manufacturing a hollow structure according to the present embodiment, the sacrifice film forming process is performed by a vapor deposition polymerization method.

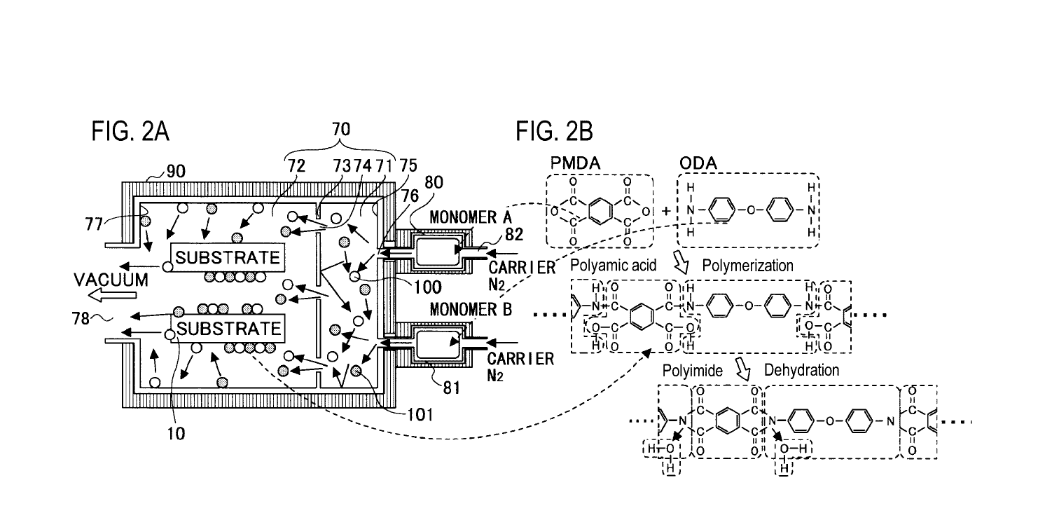

FIGS. 2A and 2B are views illustrating one example of the sacrifice film forming process using a vapor deposition polymerization method in manufacturing a hollow structure according to the first embodiment of the present disclosure. FIG. 2A is a view illustrating one example of a film forming apparatus which performs film formation of a resin film using a vapor deposition polymerization method. FIG. 2B is a view illustrating monomers as raw materials and one example of a reaction thereof.

FIG. 2A shows a state in which two substrates 10 are mounted within a chamber 70. The chamber 70 includes a preliminary mixing chamber 71 and a processing chamber 72, both of which are divided by a partition wall 73 having opening portions 74. Supply ports 76 communicating with monomer supply units 80 and 81 are formed in a sidewall 75 of the preliminary mixing chamber 71, which is opposite to the partition wall 73. The monomer supply units 80 and 81 are small chambers for vaporizing monomers and supplying the vaporized monomers to the preliminary mixing chamber 71. The monomer supply units 80 and 81 have carrier gas supply ports 82 formed at the opposite side of the supply ports 76. An exhaust port 78 is formed in a sidewall 77 of the processing chamber 72, which is opposite the partition wall 73. Except for the exhaust port 78 and the carrier gas supply ports 82, the entirety of the chamber 70 and the monomer supply units 80 and 81 is covered by a heater 90 and is configured as a hot wall type.

For example, as illustrated in FIG. 2B, pyromellitic dianhydride (PMDA) as a monomer is supplied to one monomer supply unit 80 while oxydianiline (ODA) as a monomer is supplied to the other monomer supply unit 81.

As illustrated in FIGS. 2A and 2B, PMDA is heated and vaporized by the heater 90 in the monomer supply unit 80 and is carried by a N₂ carrier gas supplied from the carrier gas supply port 82. PMDA is supplied into the preliminary mixing chamber 71 through the supply port 76 in a vapor state. Similarly, ODA is heated and vaporized by the heater 90 in the monomer supply unit 81 and is carried by a N₂ carrier gas supplied from the carrier gas supply port 82. ODA is supplied into the preliminary mixing chamber 71 through the supply port 76 in a vapor state.

Molecules 100 of PMDA and molecules 101 of ODA supplied into the preliminary mixing chamber 71 are mixed with each other within the preliminary mixing chamber 71 and are moved into the processing chamber 72 through the opening portions 74 formed in the partition wall 73.

The molecules 100 of PMDA and the molecules 101 of ODA supplied into the processing chamber 72 adhere onto the surfaces of the substrates 10. Then, a reaction at a molecular level is performed on the surfaces of the substrates 10 and a polyamic acid (polyamide acid) is generated through polymerization. Subsequently, polyimide bonding is generated through dehydration, whereby a polyimide film is formed. At this time, the dehydration is frequently generated whenever the molecules 100 of PMDA and the molecules 101 of ODA react with each other. Thus, the dehydration ends up at a molecular level. When a molecular layer of a polyimide film is generated through the dehydration, the deposition is performed on the surface of the substrate 10, so that film formation is performed in a state in which the stress generated in the polyimide film is kept very low. As mentioned above, in the vapor deposition polymerization method, dry film formation is performed under a vacuum condition. Therefore, unlike a film forming method in which a polyamide acid solution is coated on the entire surface of a substrate and a large amount of water is removed at one time by heating the polyamide acid solution, it is possible to perform film formation at low stress levels.

Furthermore, PMDA and ODA are vaporized such that the molecules 100 and 101 thereof adhere onto the surfaces of the substrates 10. For that reason, PMDA and ODA can be uniformly diffused over the surfaces of the substrates 10 having a complex shape or a minute shape. Accordingly, even if it is a concave shape having a high aspect ratio, it is possible to form a polyimide film with extremely good coverage.

The chamber 70 including the preliminary mixing chamber 71 and the processing chamber 72 is heated by the heater 90 to a temperature suitable for performing a vapor deposition reaction. The processing chamber 72 is evacuated through the exhaust port 78 by a vacuum pump or the like. Thus, the interior of the processing chamber 72 is kept in a vacuum state.

In FIGS. 2A and 2B, there is illustrated an example in which PMDA and ODA are used as source monomers. However, various resin films can be formed by appropriately changing the combination of monomers depending on the use of the hollow structure.

Furthermore, in FIGS. 2A and 2B, there is illustrated an example in which the sacrifice film forming process is performed by mounting two substrates 10 within the processing chamber 71. However, the sacrifice film forming process may be performed by a single-substrate process in which one sheet of the substrate 10 is processed. Or, the sacrifice film forming process may be performed by a batch process in which several tens of substrates 10 are processed at one time using a vertical heat treatment furnace. In addition, various methods may be used as the film forming method as long as a vapor deposition polymerization method is usable. If the vapor deposition polymerization method is used in this way, the sacrifice film forming process can be performed by various film forming methods and film forming apparatuses.

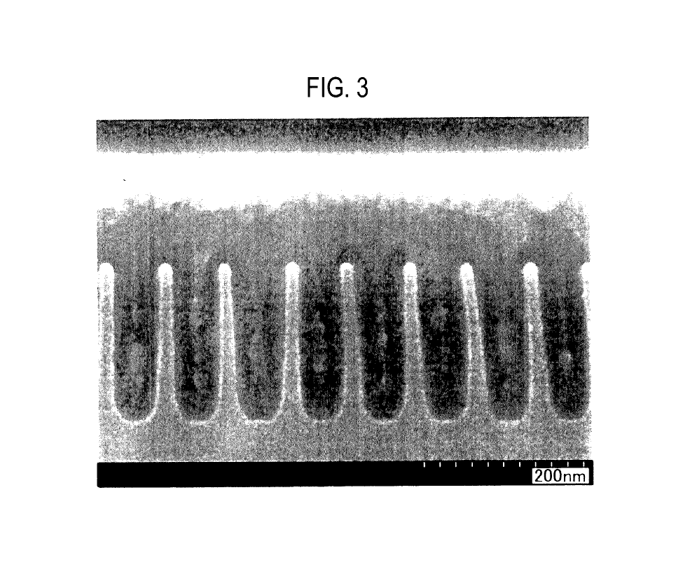

FIG. 3 is a view illustrating a state in which concave portions are buried through a vapor deposition polymerization method. The concave shapes shown in FIG. 3 are minute concave shapes having an opening width of about 20 nm and a depth of about 200 nm FIG. 3 shows that the concave portions are buried with no generation of voids and with very good coverage.

A description will be made by referring back to FIG. 1B. In FIG. 1B, the sacrifice film 40 is buried in the concave portions 22. As described above with reference to FIGS. 2 and 3, the sacrifice film 40 can be formed at a low stress by using the vapor deposition polymerization method. Even if the concave portions 22 have an opening width and a depth of a nanometer order, for example, the opening width is 10 to 100 nm and the depth is 1 to 999 nm, the sacrifice film 40 can be buried with good coverage.

FIG. 1C is a view illustrating one example of an unnecessary portion removing process. In the unnecessary portion removing process, an unnecessary portion of the sacrifice film 40 formed on the concavo-convex pattern 20 of the lower structure 30 is removed. In FIG. 1C, a region protruding upward beyond the highest convex portions 21 is regarded as the unnecessary portion. A flat surface having the same height as the outer convex portions 21 is formed by removing the protruding region. At this time, the removal of the unnecessary portion may be performed by a suitable method such as chemical mechanical polishing (CMP), dry etching, or the like.

FIG. 1D is a view illustrating one example of an upper structure forming process. In the upper structure forming process, an upper structure 50 is formed on the lower structure 30 from which the unnecessary portion of the sacrifice film 40 has been removed. The upper structure 50 is formed by, for example, depositing and forming a cover layer. In FIG. 1D, the upper structure 50 as a cover layer is formed on a flat surface defined by the upper surfaces of the convex portions 21 and the upper surface of the sacrifice film 40 filled in the concave portions 22. The upper structure 50 may be made of different materials, e.g., silicon oxide (SiO₂) film or a polysilicon film. The upper structure 50 can be formed using a film forming process of a typical semiconductor manufacturing process.

An opening portion 51 may be formed in a part of the upper structure 50. By forming the opening portion 51 in a part of the upper structure 50, the sacrifice film 40 is exposed via the opening portion 51. Thus, a medium for removing the sacrifice film 40 can be supplied to the sacrifice film 40. The formation of the opening portion 51 may be performed by many different methods. For example, the opening portion 51 may be formed by forming a resist pattern on the upper structure 50 and removing a part of the upper structure 50 by virtue of etching.

FIG. 1E is a view illustrating one example of a sacrifice film removing process. In the sacrifice film removing process, a medium for removing the sacrifice film 40 is supplied from the opening portion 51, whereby the sacrifice film 40 is removed. The removal of the sacrifice film 40 may be performed by, for example, an ashing process which makes use of an oxygen gas (O₂) as an ashing gas or a dissolution removal process which makes use of a dissolving solution (remover). If the sacrifice film 40 is removed by the ashing process, an oxygen gas is supplied from the opening portion 51, thereby burning and ashing the sacrifice film 40. If a remover is used, the remover is supplied from the opening portion 51, thereby dissolving and removing the sacrifice film 40.

As shown in FIG. 1E, by removing the sacrifice film 40, an air gap is formed between the lower structure 30 and the upper structure 50. Thus, a hollow structure is formed. As described above, in the method for manufacturing a hollow structure according to the first embodiment, the sacrifice film 40 is formed by the vapor deposition polymerization method. This makes it possible to accurately manufacture a hollow structure.

### Second Embodiment

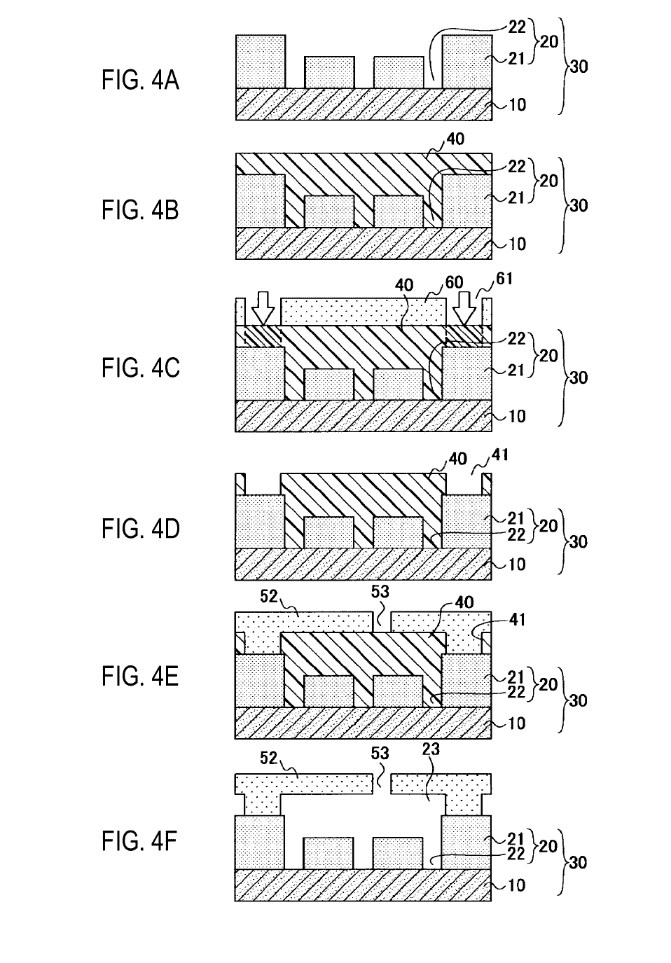

FIGS. 4A to 4F are views illustrating one example of a method for manufacturing a hollow structure according to a second embodiment of the present disclosure. In describing the method for manufacturing a hollow structure according to the second embodiment, the same elements as those described in the first embodiment will be designated by the same reference symbols to omit description thereof.

FIG. 4A is a view illustrating one example of a lower structure preparing operation. The lower structure preparing process is the same as the process shown in FIG. 1A in the method for manufacturing a hollow structure according to the first embodiment. Therefore, the respective elements will be designated by the same reference symbols to omit description thereof.

FIG. 4B is a view illustrating one example of a sacrifice film forming process. The sacrifice film forming process is the same as the process shown in FIG. 1B in the method for manufacturing a hollow structure according to the first embodiment. Therefore, the respective elements will be designated by the same reference symbols to omit description thereof.

Just like the first embodiment, the description made with reference to FIGS. 2 and 3 is applied to the sacrifice film forming process.

FIG. 4C is a view illustrating one example of an unnecessary portion removing process. In the unnecessary portion removing process, a photoresist film 60 is formed on the sacrifice film 40 formed by a vapor deposition polymerization method. The photoresist film 60 is patterned by exposure. Thus, opening portions 61 are formed. Subsequently, the sacrifice film 40 is etched using the patterned photoresist film 60 as a mask. Thus, opening portions 41 are formed.

FIG. 4D is a view illustrating one example of the sacrifice film available after the completion of the unnecessary portion removing process. The opening portions 41 are formed in both end portions of the sacrifice film 40. The upper surfaces of the convex portions 21 existing at both ends are partially exposed. Thus, a concavo-convex pattern is formed. As mentioned above, in the unnecessary portion removing process, the sacrifice film 40 can be patterned not only by merely flattening the sacrifice film 40 but also by removing an unnecessary portion as a pattern of the sacrifice film 40. This makes it possible to form an air gap into different shapes.

FIG. 4E is a view illustrating one example of an upper structure forming process. In the upper structure forming process, an upper structure 52 is formed on the surface of the lower structure 30 including the concavo-convex pattern of the sacrifice film 40 formed in the unnecessary portion removing process. Just like the first embodiment, the upper structure 52 may be formed as a cover layer which covers the lower structure 30 including the sacrifice film 40. In this case, the cover layer is deposited on the surface of the lower structure 30 including the concavo-convex pattern. Thus, the lower surface of the cover layer is formed into a shape which conforms to the concavo-convex pattern. That is to say, in the first embodiment, the lower surface of the upper structure 50 is a flat surface. However, in the second embodiment, the lower surface of the upper structure 50 is configured to be buried in the opening portions 41. The upper structure forming process according to the second embodiment is the same as that of the first embodiment at other points, for example, at the point that the upper structure 52 may be a film used in a semiconductor manufacturing process, such as a SiO₂ film or a polysilicon film. Therefore, the description thereof will be omitted.

An opening portion 53 for exposing the sacrifice film 40 is formed in a part of the upper structure 52. This point is just like that of the first embodiment. Therefore, the description thereof will be omitted.

FIG. 4F is a view illustrating one example of a sacrifice film removing process. In the sacrifice film removing process, the sacrifice film 40 is removed to form an air gap between the upper structure 52 and the lower structure 30. Unlike the first embodiment, the air gap is shaped such that the upper structure 52 is formed at a higher location. The air gap 23 is larger than the size of the concave portions 22 of the first embodiment.

As described above, in the method for manufacturing a hollow structure according to the second embodiment, the air gap 23 can be formed into different shapes by patterning the sacrifice film 40 in the unnecessary portion removing step.

In the second embodiment, there has been described an example in which the sacrifice film 40 is formed into a pattern having the opening portions 41 at both ends thereof. However, the sacrifice film 40 may be formed into different patterns depending on the use of the hollow structure.

The processing contents of the sacrifice film removing process is the same as those of the first embodiment illustrated in FIG. 1E. Therefore, the description thereof will be omitted.

### Third Embodiment

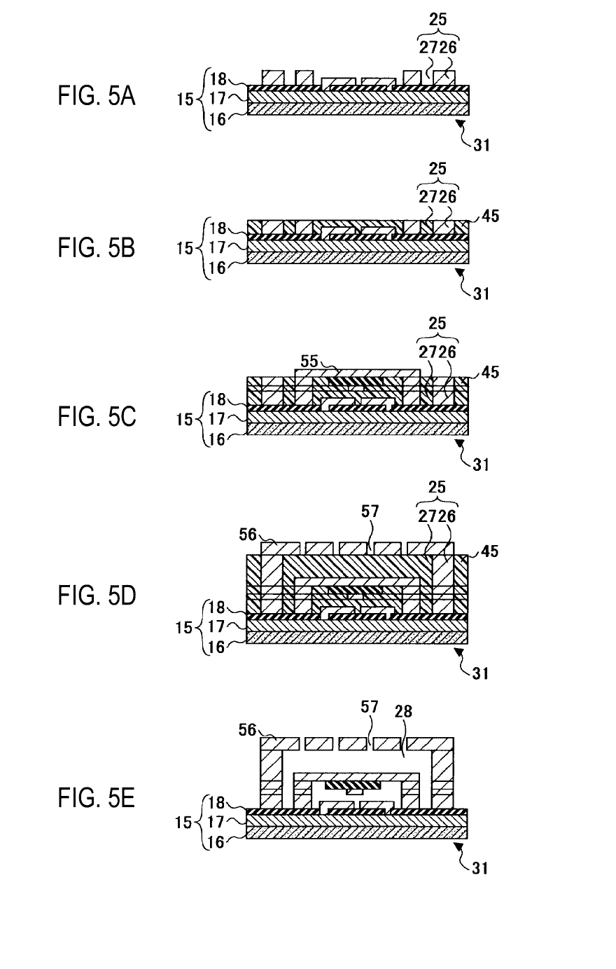

FIGS. 5A to 5E are views illustrating one example of a method for manufacturing a hollow structure according to a third embodiment of the present disclosure. In the method for manufacturing a hollow structure according to the third embodiment, an example of manufacturing a hollow structure having a more complex shape than those of the first and second embodiments will be described.

FIG. 5A is a view illustrating one example of a lower structure preparing process. FIG. 5A illustrates a state in which a lower structure 31 configured by forming a concavo-convex pattern 25 on a substrate 15 is prepared. The substrate 15 is configured with three layers, namely a silicon substrate 16, a metal wiring layer 17 and an insulating layer 18. A concavo-convex pattern 25 including convex portions 26 and concave portions 27 are formed on the surface of the substrate 15, namely on the surface of the insulating layer 18. The convex portions 26 may be made of a metallic material such as, e.g., gold. The convex portions 26 may be formed by plating. In view of this point, the lower structure preparing process illustrated in FIG. 5A may be called a plating process.

FIG. 5B is a view illustrating one example of a sacrifice film forming process and a planarization process. As illustrated in FIG. 5B, a sacrifice film 45 is formed on the lower structure 31 so as to bury the concavo-convex pattern 25 including the concave portions 27. Moreover, the surface of the sacrifice film 45 is flattened. In FIG. 5B, there are illustrated the lower structure 31 and the sacrifice film 45, both of which have gone through the processes illustrated in FIGS. 1B and 1C of the first embodiment.

The formation of the sacrifice film 45 is performed by a vapor deposition polymerization method. It is therefore possible to form the sacrifice film 45 at a low stress and with good coverage. The sacrifice film 45 may be any of different organic films that can be formed by a vapor deposition polymerization method. For example, the sacrifice film 45 may be a polyimide film.

FIG. 5C is a view illustrating one example of a first upper structure forming process. In the first upper structure forming process, a first upper structure 55 is formed so as to interconnect two internal convex portions 26. In this case, just like the convex portions 26, the first upper structure 55 is made of a metallic material such as gold or the like. When forming the first upper structure 55, the height of the convex portions 26 and the sacrifice film 45 is increased by repeating, more than once, the plating process, the sacrifice film forming process and the planarization process illustrated in FIGS. 5A and 5B. Thereafter, the entire surface is plated and a pattern is formed by etching. In the process illustrated in FIG. 5C, the aspect ratio of the concave portions 27 grows larger. In the method for manufacturing a hollow structure according to the present embodiment, the sacrifice film 45 is formed by the vapor deposition polymerization method. It is therefore possible to deposit the sacrifice film 45 with high buriability without generating voids on the side surface and the bottom surface.

FIG. 5D is a view illustrating one example of a second upper structure forming process. In the second upper structure forming process, the height of the convex portions 26 existing at both ends and the height of the sacrifice film 45 filling the concave portions 27 are increased through the plating process, the sacrifice film forming process and the planarization process, which are illustrated in FIGS. 5A and 5B. Thereafter, the entire surface is plated and a second upper structure 56 is patterned and formed by etching. Unlike the first upper structure 55, the second upper structure 56 has opening portions 57. When patterning the second upper structure 56, it is possible to pattern the second upper structure 56 into an arbitrary shape. Thus, the second upper structure 56 can be formed into different shapes depending on the use of the hollow structure. Dual sidewalls and dual upper surfaces are formed through the second upper structure forming process.

FIG. 5E is a view illustrating one example of a sacrifice film removing process. In the sacrifice film removing process, an oxygen gas or a dissolving solution for removing the sacrifice film 45 is supplied from the opening portions 57, whereby the sacrifice film 45 is removed by decomposition and/or dissolution. Thus, an air gap 28 is formed between the lower structure 31 and the first and second upper structures 55 and 56. In FIGS. 5C to 5E, opening portions are not indicated in the first upper structure 55. However, if opening portions are formed at the positions on a cross section differing from the cross section of FIGS. 5C to 5E, the sacrifice film 45 existing between the first upper structure 55 and the lower structure 31 can be removed at one time in the sacrifice film removing process by supplying a removing medium from the opening portions 57.

As illustrated in FIG. 5E, even if the hollow structure has a complex structure, an air gap can be accurately formed by the method for manufacturing a hollow structure according to the present embodiment.

In FIGS. 5A to 5E, there is illustrated an example in which a three-layer substrate composed of three layers, namely the silicon substrate 16, the metal wiring layer 17 and the insulating layer 18, is used as the substrate 15. However, the substrate 15 may be appropriately selected depending on the use of the hollow structure. For example, the substrate 15 may be composed of only the silicon substrate 16.

While some embodiments of the present disclosure have been described above in detail, the present disclosure is not limited to the aforementioned embodiments. The embodiments described above may be differently modified or substituted without departing from the scope of the present disclosure.

The subject international application claims priority to Japanese Patent Application No. 2013-68958 filed on Mar. 28, 2013, the entire disclosure of which is incorporated herein by reference.

What is claimed is:

1. A method for manufacturing a hollow structure, comprising:
preparing a lower structure which includes a concave portion;
depositing a sacrifice film composed of an organic film on the lower structure by a vapor deposition polymerization method to bury the concave portion with the sacrifice film;
removing an unnecessary portion of the sacrifice film;
forming an upper structure on the sacrifice film with the unnecessary portion removed; and
forming an air gap between the lower structure and the upper structure by removing the sacrifice film.

2. The method of claim 1, wherein the concave portion is buried by using a polyimide film as the sacrifice film.

3. The method of claim 1, wherein the removing the unnecessary portion includes forming a flat surface by removing the sacrifice film deposited above the concave portion.

4. The method of claim 3, wherein the forming the flat surface is performed by chemical mechanical polishing or dry etching.

5. The method of claim 3, wherein the forming the upper structure includes forming a cover layer on the flat surface.

6. The method of claim 1, wherein the removing the unnecessary portion of the sacrifice film includes forming a resist pattern on the sacrifice film, removing an unnecessary portion and patterning the sacrifice film.

7. The method of claim 6, wherein the forming the upper structure includes forming a cover layer on the patterned sacrifice film.

8. The method of claim 1, wherein, in the forming the air gap, the sacrifice film is removed by ashing or by supplying a dissolving solution.

9. The method of claim 5, wherein the forming the upper structure includes forming an opening in a part of the cover layer to expose an upper surface of the sacrifice film, and
in the forming the air gap, the sacrifice film is removed by supplying an ashing gas or a dissolving solution from the opening.

10. The method of claim 1, wherein the concave portion is formed so as to have a nanometer-order opening width and depth.

11. The method of claim 10, wherein the opening width ranges from 10 to 100 nm and the depth ranges from 1 to 999 nm.
